(19) United States
(12) Patent Application Publication
(10) Pub. No.: US 2019/0006219 A1
(43) Pub. Date: Jan. 3, 2019

(54) METHOD OF PACKAGING CHIP AND CHIP PACKAGE STRUCTURE

(71) Applicants: BOE TECHNOLOGY GROUP CO., LTD., Beijing (CN); BEIJING BOE DISPLAY TECHNOLOGY CO., LTD., Beijing (CN)

(72) Inventors: Yonglian QI, Beijing (CN); Lianjie QU, Beijing (CN); Zhidong WANG, Beijing (CN); Yuanxin DU, Beijing (CN); Hebin ZHAO, Beijing (CN); Yun QIU, Beijing (CN)

(21) Appl. No.: 15/916,114

(22) Filed: Mar. 8, 2018

(30) Foreign Application Priority Data
Jul. 3, 2017 (CN) 201710536776.9

(51) Int. Cl. H01L 21/683; H01L 21/56; H01L 23/00; H01L 23/31

(52) U.S. Cl. CPC H01L 21/683; H01L 2221/68381; H01L 21/568; H01L 24/24; H01L 24/25; H01L 24/82; H01L 23/3185; H01L 24/02; H01L 2224/02379; H01L 24/13; H01L 2224/13024; H01L 2924/18162; H01L 2224/24137; H01L 2224/25171; H01L 2224/82005; H01L 2221/68359; H01L 2221/68313; H01L 21/561

(57) ABSTRACT

A method of packaging a chip includes laminating a first substrate with a second substrate, the first substrate being capable of withstanding a greater stress than the second substrate; applying an adhesive layer on the second substrate; bonding the chip on the adhesive layer; and forming an encapsulation layer that covers at least the chip.

### CROSS REFERENCE TO RELATED APPLICATIONS

This application claims the benefit of Chinese Patent Application No. 201710536776.9 filed on Jul. 3, 2017, the entire disclosure of which is incorporated herein by reference.

### TECHNICAL FIELD

The present disclosure relates to the field of semiconductor technology, and particularly to a method of packaging a chip and a chip package structure.

### BACKGROUND

Silicon wafers are used in the conventional semiconductor industry as a substrate on which chips are packaged, which wafers typically have a dimension of, for example, 6, 8, or 12 inches, resulting in limited yielding efficiency. In contrast, glass substrates of much larger dimensions (e.g., 2 m×2 m) can be used in the display industry, making higher yielding efficiency possible. However, silicon wafer-based chip packaging approaches are generally considered unsuitable for glass substrates because glass is not capable of withstanding the same stress as silicon wafers.

### SUMMARY

It would be advantageous to provide a solution that may alleviate, mitigate or eliminate one or more of the above problems.

According to an aspect of the present disclosure, a method of packaging a chip is provided, comprising laminating a first substrate with a second substrate, the first substrate being capable of withstanding a greater stress than the second substrate; applying an adhesive layer on the second substrate; bonding the chip on the adhesive layer; and forming an encapsulation layer that covers at least the chip.

In certain exemplary embodiments, the method further comprises unsealing a portion of the encapsulation layer to expose a portion of the chip; forming a redistribution layer and solder balls above the chip and the encapsulation layer; and removing the adhesive layer, the first substrate and the second substrate.

In certain exemplary embodiments, the removing is achieved by a process comprising at least one selected from the group consisting of heating the adhesive layer and irradiating the adhesive layer.

In certain exemplary embodiments, the first substrate and the second substrate have a panel-level size.

In certain exemplary embodiments, the method further comprises forming a groove in the second substrate prior to the applying. The bonding comprises bonding the chip on the adhesive layer within the groove.

In certain exemplary embodiments, the laminating comprises applying glue at a periphery of at least one of the first substrate or the second substrate; stacking the first substrate and the second substrate on top of each other; and vacuumizing a space defined by the first substrate and the second substrate.

In certain exemplary embodiments, the forming the groove comprises forming the groove on a side of the second substrate away from the first substrate.

In certain exemplary embodiments, the groove has a depth equal to or less than a thickness of the second substrate.

In certain exemplary embodiments, in a plane perpendicular to a depth direction of the groove, the groove has a size larger than a size of the chip.

In certain exemplary embodiments, the groove is formed such that an upper surface of the bonded chip away from the first substrate protrudes from an upper surface of the second substrate away from the first substrate.

In certain exemplary embodiments, the first substrate is a tempered glass substrate.

In certain exemplary embodiments, the second substrate is a glass substrate.

According to another aspect of the present disclosure, a chip package structure is provided, comprising a plurality of chips spaced apart from each other; an encapsulation layer arranged at least between the chips to interconnect the chips with each other; a redistribution layer arranged beyond an upper surface of the chips such that at least a portion of the redistribution layer is above the encapsulation layer; and solder balls electrically connected to the redistribution layer. A portion of the encapsulation layer between the chips forms a recess structure having an opening facing away from the upper surface of the chips.

In certain exemplary embodiments, the recess structure has a depth substantially defined by a thickness of the chips.

In certain exemplary embodiments, the encapsulation layer has a panel-level size such that the chip package structure is a panel-level fan-out package.

These and other aspects of the present disclosure will be apparent from and elucidated with reference to the embodiment(s) described hereinafter.

### BRIEF DESCRIPTION OF THE DRAWINGS

Further details, features and advantages of the disclosure are disclosed in the following description of exemplary embodiments in connection with the accompanying drawings, in which:

FIG. 1 is a flowchart of a chip packaging method according to an embodiment of the present disclosure;

FIG. 2 is a cross-sectional view illustrating a structure obtained by laminating a first substrate with a second substrate;

FIG. 3 is a cross-sectional view illustrating a structure obtained by applying an adhesive layer on the basis of FIG. 2;

FIG. 4 is a cross-sectional view illustrating a structure obtained by placing chips on the basis of FIG. 3;

FIG. 5 is a cross-sectional view illustrating a structure obtained by forming an encapsulation layer on the basis of FIG. 4;

FIG. 6 is a cross-sectional view illustrating a structure obtained by unsealing a portion of the encapsulation layer on the basis of FIG. 5;

FIG. 7 is a cross-sectional view illustrating a structure obtained by forming a redistribution layer and solder balls on the basis of FIG. 6;

FIG. 8 is a cross-sectional view illustrating a chip package structure according to an embodiment of the present disclosure, obtained by removing the adhesive layer, the first substrate and the second substrate on the basis of FIG. 7;

FIG. 9 is a flowchart of a chip packaging method according to another embodiment of the present disclosure;

FIG. 10 is a cross-sectional view illustrating a structure obtained by laminating a first substrate with a second substrate having a plurality of grooves;

FIG. 11 is a cross-sectional view illustrating a structure obtained by applying an adhesive layer on the basis of FIG. 10;

FIG. 12 is a cross-sectional view illustrating a structure obtained by placing chips on the basis of FIG. 11;

FIG. 13 is a cross-sectional view illustrating a structure obtained by forming an encapsulation layer on the basis of FIG. 12;

FIG. 14 is a cross-sectional view illustrating a structure obtained by unsealing a portion of the encapsulation layer on the basis of FIG. 13;

FIG. 15 is a cross-sectional view illustrating a structure obtained by forming a redistribution layer and solder balls on the basis of FIG. 14; and

FIG. 16 is a cross-sectional view illustrating a chip package structure according to an embodiment of the present disclosure, obtained by removing the adhesive layer, the first substrate, and the second substrate on the basis of FIG. 15.

### DETAILED DESCRIPTION

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another. Thus, a first element, component, region, layer or section discussed below could be termed a second element, component, region, layer or section without departing from the teachings of the present disclosure.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. Terms such as “before” or “preceding” and “after” or “followed by” may be similarly used, for example, to indicate an order in which light passes through the elements. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present. In no event, however, should “on” or “directly on” be construed as requiring a layer to completely cover an underlying layer.

Embodiments of the disclosure are described herein with reference to schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Embodiments of the present disclosure are described in detail below with reference to the accompanying drawings.

FIG. 1 is a flowchart of a chip packaging method 100 according to an embodiment of the present disclosure.

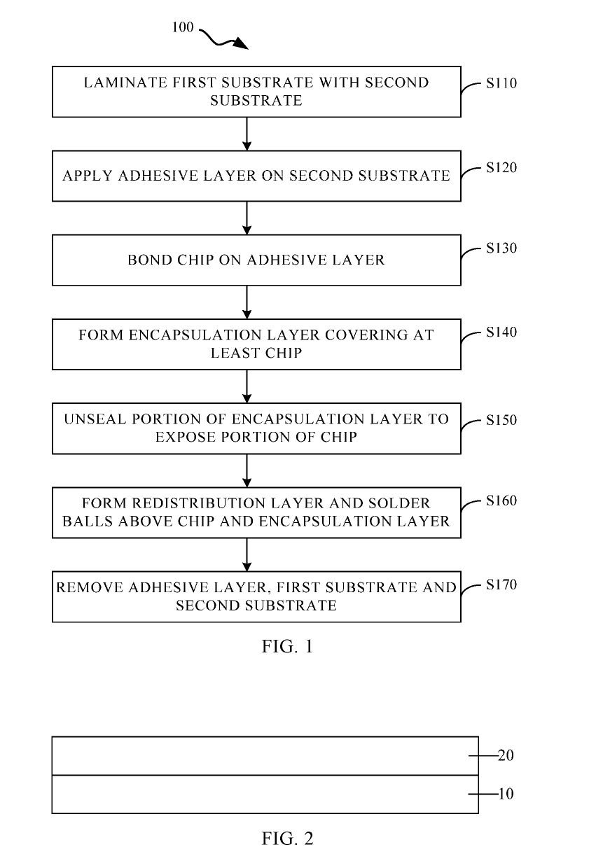

At step S110, a first substrate 10 is laminated with a second substrate 20, as shown in FIG. 2. The first substrate 10 is capable of withstanding greater stress than the second substrate 20. This provides enhanced mechanical strength for the first and second substrates 10, 20 as a whole, allowing for subsequent chip packaging. In this embodiment, the first and second substrates 10, 20 may be made of any suitable material and may have any desired size. For example, the first and second substrates 10, 20 may have a panel-level size (i.e., comparable to the size of a substrate used in the display industry) so as to achieve panel-level fan-out packaging. In addition, the first substrate 10 and the second substrate 20 may have any desired shape, such as, e.g., a rectangle or other regular polygons.

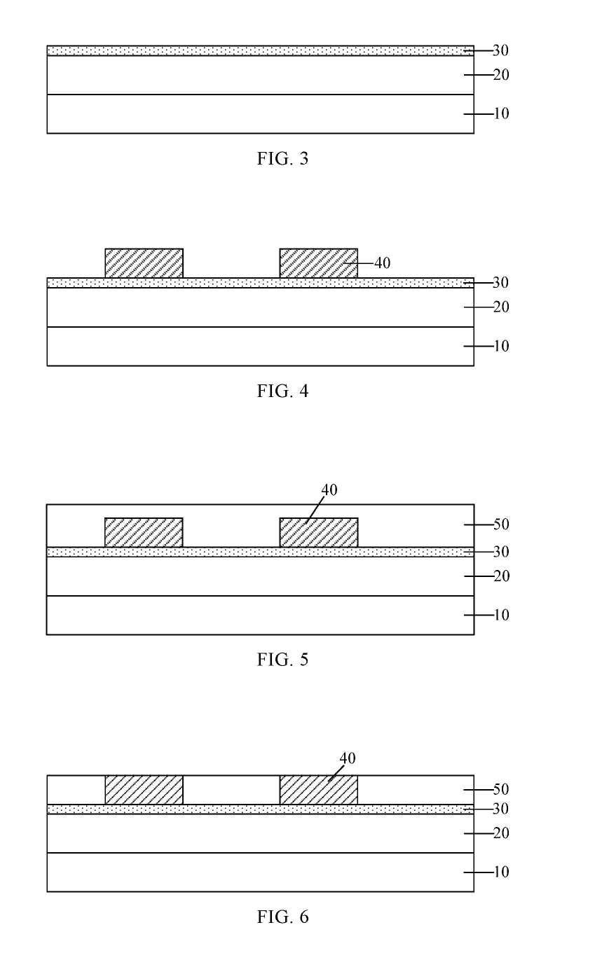

At step S120, an adhesive layer 30 is applied on the second substrate 20, as shown in FIG. 3. Here, the adhesive layer 30 is a double-sided adhesive so that it can be bonded to the second substrate 20 and can bond chips in a subsequent process.

At step S130, chip(s) 40 is(are) bonded on the adhesive layer 30, as shown in FIG. 4. The chip 40 may be placed at a predetermined position on the second substrate 20 using, for example, a chip mounter. Although only two chips 40 are shown in FIG. 4, depending on the size of the second substrate 20 and the chips 40, tens of, hundreds of, or even more chips 40 may be placed in respective positions on the second substrate 20 and fixed by the adhesive layer 30 in a panel-level fan-out packaging application. The chip 40 may include a semiconductor device or integrated circuit that has already been fabricated on a semiconductor substrate. For example, the chip 40 may include a substrate that includes silicon or other semiconductor material, an insulating layer on the substrate, conductive features (including metal pads, plugs, vias, or wires, for example), and contact pads above the conductive features.

At step S140, an encapsulation layer 50 is formed that covers at least the chip 40, as shown in FIG. 5. The encapsulation layer 50 serves to protect the chip 40.

In the method 100, by making the underlying first substrate 10 capable of withstanding greater stress than the upper second substrate 20, the bending resistance and impact resistance of the substrates as a whole are increased, thus avoid bending or even cracking of the second substrate 20 when the chip 40 is packaged on the second substrate 20. Moreover, the first and second substrates 10, 20 may have a much larger size than silicon wafers, making it possible to achieve panel-level fan-out packaging, and thereby improving packaging efficiency as well as yielding efficiency.

The method 100 may optionally further include steps S150 to S170, as shown in FIG. 1.

At step S150, a portion of the encapsulation layer 50 is unsealed to expose a portion of the chip 40, as shown in FIG. 6. The purpose of unsealing is to expose the chip 40 for making a redistribution layer (RDL). Unsealing can be achieved by, for example, dry etching or wet etching. In the example of FIG. 6, an upper surface of the chip 40 is exposed.

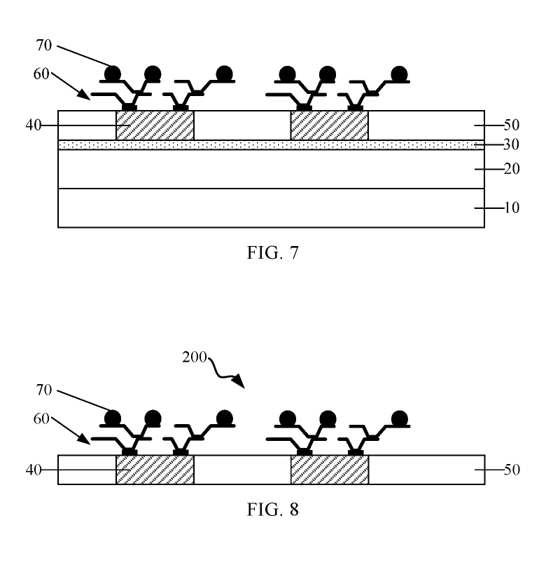

At step S160, a redistribution layer 60 and solder balls 70 are formed above the chip 40 and the encapsulation layer 50, as shown in FIG. 7. The redistribution layer 60 makes an electrical connection with contact pads (not shown) on the chip 40. The redistribution layer 60 is arranged beyond the upper surface of the chip 40 to form a fan-out, thereby allowing for better connectivity and design flexibility. The redistribution layer 60 may be made of, for example, copper or a copper alloy. The redistribution layer 60 may be formed in a dielectric layer (not shown). Solder balls 70 may be made of a metallic material such as, e.g., tin, lead, copper, silver, gold, bismuth, or alloys thereof. The method of forming the solder balls 70 includes printing, balling, laser sintering, electroplating, electroplating, sputtering and the like.

At step S170, the adhesive layer 30, the first substrate 10 and the second substrate 20 are removed, obtaining a resultant chip package structure 200 as shown in FIG. 8. The removal of the adhesive layer 30, the first substrate 10, and the second substrate 20 may be achieved by treating the adhesive layer 30 using, for example, heating, irradiating or other processes to separate the chip 40 and the encapsulation layer 50 from the adhesive layer 30 (and potentially the first and second substrates 10, 20). Heating and irradiating typically prevent damage to the chip 40 and are easy to perform. Thus, in some embodiments, the adhesive layer 30 may be of a thermal stripping property and/or an irradiation (e.g., UV irradiation) stripping property. Where the adhesive layer 30 is of a thermal stripping property, the adhesive layer 30 may, for example, be a double-sided adhesive. In this case, the first substrate 10 and the second substrate 20 may be transparent or opaque. Where the adhesive layer 30 is of an irradiation stripping property, the adhesive layer 30 may, for example, be a UV light stripping adhesive. In this case, the first substrate 10 and the second substrate 20 are transparent.

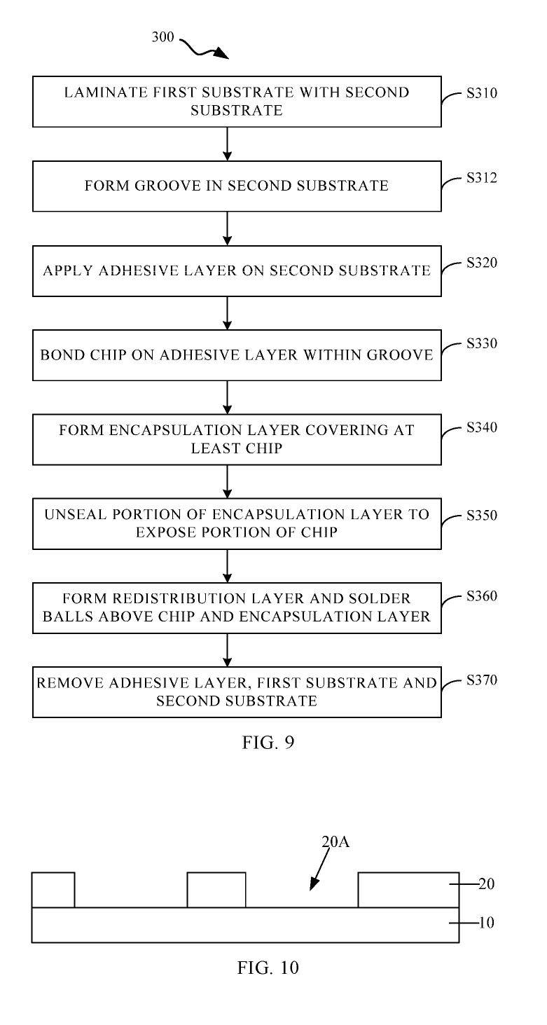

FIG. 9 is a flowchart of a chip packaging method 300 according to another embodiment of the present disclosure. As shown in FIG. 9, the method 300 includes steps S310 to S340 and optionally steps S350 to S370. Unlike the method 100 described above, the second substrate 20 used in the method 300 is provided with a plurality of grooves 20A. More details of the method 300 are described below.

At step S310, a first substrate 10 is laminated with a second substrate 20. Similar to the method 100, the first substrate 10 is capable of withstanding greater stress than the second substrate 20. This may provide the same advantages as the method 100 as described above. For example, the first substrate 10 and the second substrate 20 may have a panel-level size to enable panel-level fan-out packaging. Step S310 may be achieved by gluing a periphery of the first substrate 10 and/or the second substrate 20, stacking the first substrate 10 and the second substrate 20 on top of each other, and vacuumizing a space defined by the first substrate 10 and the second substrate 20. In some exemplary embodiments, the first substrate 10 may be made of tempered glass, and the second substrate 20 may be made of glass or other low-stress material. Other embodiments are also contemplated.

At step S312, a plurality of grooves 20A are formed on a side of the second substrate 20 away from the first substrate 10, as shown in FIG. 10. The grooves 20A may be formed by, for example, laser etching or etchant wet etching. Although step S312 is shown in FIG. 9 subsequent to step S310, the present disclosure is not limited thereto. For example, the plurality of grooves 20A may be formed in the second substrate 20 prior to step S310, and then the first substrate 10 and the second substrate 20 in which the grooves 20A are formed are laminated together. In either case, the grooves 20A may have a thickness equal to a thickness of the second substrate 20, i.e., the grooves 20A are through-holes as shown in FIG. 10. Alternatively, the grooves 20A may have a thickness smaller than the thickness of the second substrate 20, i.e., the grooves 20A are blind holes (not shown). In addition, in a plane perpendicular to a depth direction of the groove 20A, the groove 20A may have a size larger than that of the chip 40 to ensure that the chip 40 can be completely placed within the groove 20A, although other embodiments are possible.

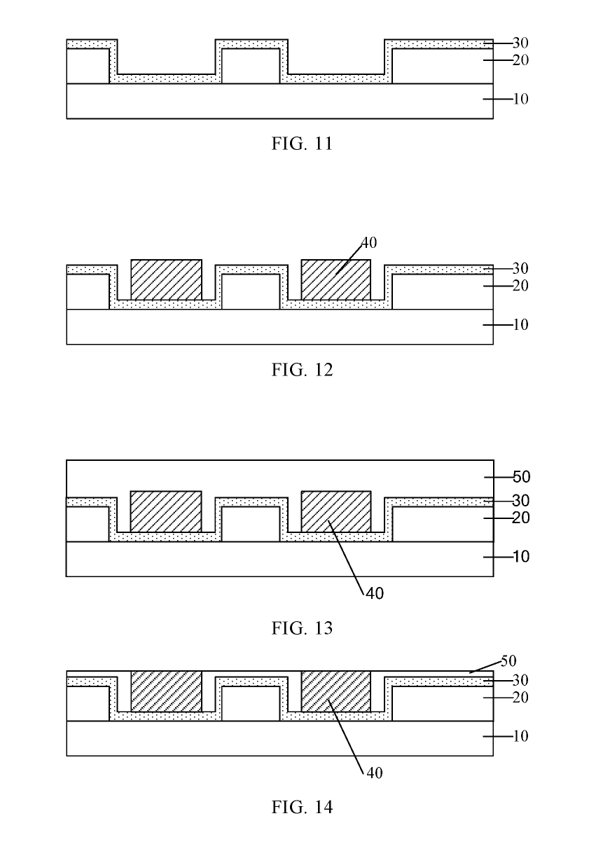

At step S320, an adhesive layer 30 is formed on the second substrate 20, as shown in FIG. 11. Step S320 is similar to step S120 described above in connection with FIGS. 1 and 3, and is not repeated here.

At step S330, the chips 40 are bonded on the adhesive layer 30 within the grooves 20A, as shown in FIG. 12. Two chips 40 and two grooves 20A are shown in FIG. 12. In this example, each chip 40 is placed in a corresponding recess 20A. Placing the chip 40 within the groove 20A would be advantageous in that this provides a smaller step between the upper surface of the chip 40 and the upper surface of the second substrate 20, thereby reducing the difficulty for subsequent processes. As will be further described below, due to the raised portion of the second substrate 20 between adjacent grooves 20A, it is also possible to reduce the amount of encapsulation material used in the subsequent steps, thereby reducing the stress withstood by the first and second substrates 10, 20. In the example of FIG. 12, the upper surface of the chips 40 away from the first substrate 10 protrudes from the upper surface of the second substrate 20 away from the first substrate 10. This can further reduce the amount of encapsulation material used in subsequent packaging steps, and the chips 40 can be more easily exposed in the subsequent unsealing step. Alternatively, the upper surface of the chips 40 away from the first substrate 10 may be flush with or lower than the upper surface of the second substrate 20 away from the first substrate 10.

At step S340, an encapsulation layer 50 is formed that covers at least the chip 40, as shown in FIG. 13. In some exemplary embodiments, the encapsulation layer 50 may be made of epoxy molding compound (EMC) which can provide good sealing. Since the chip 40 has been placed in the groove 20A at step S330, the encapsulation material required to form the encapsulation layer 50 is greatly reduced. As mentioned above, this would be advantageous in that the reduced encapsulation material means reduced stress applied to the first and second substrates 10, 20.

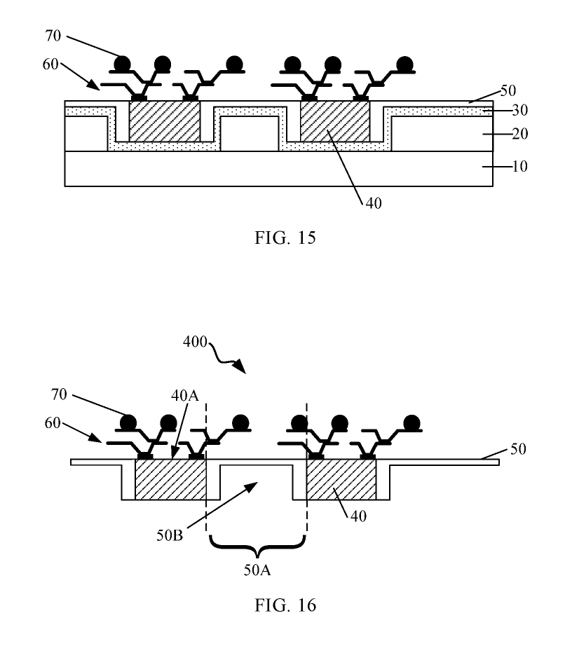

The method 300 may optionally further include steps S350 to S370, as shown in FIG. 9. Steps S350 to S370 are similar to steps S150 to S170 described above in connection with FIGS. 1 and 6-8. At step S350, a portion of the encapsulation layer 50 is unsealed to expose a portion of the chip 40, as shown in FIG. 14. At step S360, a redistribution layer 60 and solder balls 70 are formed above the chips 40 and the encapsulation layer 50, as shown in FIG. 15. At step S370, the adhesive layer 30, the first substrate 10 and the second substrate 20 are removed to obtain a resultant chip package structure 400, as shown in FIG. 16.

In the example of FIG. 16, the chip package structure 400 includes a plurality of chips 40 (only two of them are shown in FIG. 16) that are spaced apart from one another, an encapsulation layer 50, a redistribution layer 60, and solder balls 70 electrically connected with the redistribution layer 60. The encapsulation layer 50 is arranged between at least the chips 40 to interconnect the chips 40 with each other. The redistribution layer 60 is arranged beyond the upper surface 40A of the chips 40 such that at least a portion of the redistribution layer 60 is above the encapsulation layer 50.

Due to the use of the second substrate 20 with the grooves 20A in the fabrication process, in the resulting chip package structure 400, a portion 50A of the encapsulation layer 50 between the chips 40 (which roughly corresponds to the portion of the second substrate 20 where there are no grooves) forms a recess structure 50B that has an opening facing away from the upper surface 40A of the chips 40, as shown in FIG. 16. The recess structure 50B has a depth substantially defined by the thickness of the chips 40. The term “substantially” as used herein means that the depth of the recess structure 50B is defined by 50% or more of the thickness of the chips 40. In some exemplary embodiments, the encapsulation layer 50 has a panel-level size such that the chip encapsulation structure 400 is a panel-level fan-out package. In particular, the resulting chip package structure 400 provides additional advantages described above as compared to the structure 200 due to the presence of the grooves 20A in the second substrate 20.

The foregoing are merely specific embodiments of the present disclosure, and the scope of the present disclosure is not limited thereto. Any variation or replacement that can be easily conceived of by those skilled in the art after studying this disclosure shall fall within the scope of the present disclosure. Therefore, the scope of the present disclosure should be subject to the appended claims.

What is claimed is:

1. A method of packaging a chip, comprising:
laminating a first substrate with a second substrate, wherein the first substrate is capable of withstanding a greater stress than the second substrate;
applying an adhesive layer on the second substrate;
bonding the chip on the adhesive layer; and
forming an encapsulation layer that covers at least the chip.

2. The method of claim 1, further comprising:
unsealing a portion of the encapsulation layer to expose a portion of the chip;
forming a redistribution layer and solder balls above the chip and the encapsulation layer; and
removing the adhesive layer, the first substrate and the second substrate.

3. The method of claim 2, wherein the removing is achieved by a process comprising at least one selected from the group consisting of heating the adhesive layer and irradiating the adhesive layer.

4. The method of claim 1, wherein the first substrate and the second substrate have a panel-level size.

5. The method of claim 1, further comprising forming a groove in the second substrate prior to the applying, wherein the bonding comprises bonding the chip on the adhesive layer within the groove.

6. The method of claim 5, wherein the laminating comprises:
applying glue at a periphery of at least one of the first substrate or the second substrate;
stacking the first substrate and the second substrate on top of each other; and
vacuumizing a space defined by the first substrate and the second substrate.

7. The method of claim 6, wherein the forming the groove comprises forming the groove on a side of the second substrate away from the first substrate.

8. The method of claim 5, wherein the groove has a depth equal to or less than a thickness of the second substrate.

9. The method of claim 5, wherein in a plane perpendicular to a depth direction of the groove, the groove has a size larger than a size of the chip.

10. The method of claim 5, wherein the groove is formed such that an upper surface of the bonded chip away from the first substrate protrudes from an upper surface of the second substrate away from the first substrate.

11. The method of claim 1, wherein the first substrate is a tempered glass substrate.

12. The method of claim 1, wherein the second substrate is a glass substrate.

13. A chip package structure, comprising:
a plurality of chips spaced apart from each other;
an encapsulation layer arranged at least between the chips to interconnect the chips with each other;
a redistribution layer arranged beyond an upper surface of the chips such that at least a portion of the redistribution layer is above the encapsulation layer; and
solder balls electrically connected to the redistribution layer;
wherein a portion of the encapsulation layer between the chips forms a recess structure having an opening facing away from the upper surface of the chips.

14. The chip package structure of claim 13, wherein the recess structure has a depth substantially defined by a thickness of the chips.

15. The chip package structure of claim 13, wherein the encapsulation layer has a panel-level size such that the chip package structure is a panel-level fan-out package.
